(19) United States
(12) Patent Application Publication
(10) Pub. No.: US 2016/0334168 A1
(43) Pub. Date: Nov. 17, 2016

(54) COOLING DEVICE AND ELECTRONIC DEVICE PROVIDED WITH COOLING DEVICE

(71) Applicant: Hitachi, Ltd., Tokyo (JP)

(72) Inventors: Kazuaki SUZUKI, Tokyo (JP); Shigeyasu TSUBAKI, Tokyo (JP); Shigemasa SATOU, Tokyo (JP)

(73) Assignee: Hitachi, Ltd., Tokyo (JP)

(21) Appl. No.: 15/111,349

(22) PCT Filed: Jan. 27, 2014
(86) PCT No.: PCT/JP2014/051607

§ 371 Date: Jul. 13, 2016

(51) Int. Cl. F28D 15/02; H05K 7/20; F28F 13/00; F28D 15/04; F28F 3/02

(52) U.S. Cl. CPC F28D 15/0266; F28D 15/046; F28F 3/022; F28F 13/003; H05K 7/20809; H05K 7/20727; F28D 2015/0216; F28D 2021/0028

(57) ABSTRACT

Provided are: a cooling device that makes it possible to achieve sufficient cooling performance even within a thin electronic device; and an electronic device that is provided with the cooling device. The cooling device is provided with: a heat reception unit that vaporizes a refrigerant; a condensation unit that condenses the vaporized refrigerant and that comprises a vapor tube through which the vaporized refrigerant moves, an inclined section that has inclines in at least two directions, and at least two members that are connected to the inclines; and a liquid tube through which the condensed liquid refrigerant moves.

### TECHNICAL FIELD

The present invention relates to a cooling device and an electronic device provided with the cooling device.

### BACKGROUND ART

In recent years, in accordance with high functionality and high integration of electronic devices represented by a server, the heating value of incorporated semiconductor devices such as CPU has increased. In these semiconductor devices, since it is impossible to maintain the performance when the temperature exceeds a predetermined value, temperature control such as cooling is required.

As a background art of the present technical field, Japanese Patent Application Publication No. 2011-47616 (Patent Literature 1) is known. This publication discloses a description “provided are a cooling system utilizing a thermo-siphon with excellent energy-saving and ecological measures by efficient cooling, and a structure of electronic device appropriate to the system” (see Abstract).

### CITATION LIST

### Patent Literature

Patent Literature 1: Japanese Patent Application Publication No. 2011-47616

### SUMMARY OF INVENTION

### Technical Problem

Patent Literature 1 discloses a cooling system to condense refrigerant from vapor to liquid with a flat tube of a condenser. However, when the cooling system in Patent Literature 1 is installed in a thin electronic equipment (electronic device) such as a rack-mount type server or a blade server having a height of 1 U (1.75 inches=44.45 mm), the space in the height direction for installation of the flat tube of the condenser is very small. Since it is impossible to sufficiently condense the refrigerant with a low flat tube, the cooling performance of the cooling system is seriously lowered.

Accordingly, the present invention provides a cooling device to exert sufficient cooling performance even in e.g. a thin electronic device, and an electronic device having the cooling device.

### Solution to Problem

To solve the above problem, the present invention has: a heat reception unit that vaporizes refrigerant; a condensation unit, a vapor tube through which the vaporized refrigerant moves, an inclined section having inclines in at least two directions, and two or more members connected with the inclines of the inclined section, that condenses the vapor refrigerant; and a liquid tube through which the condensed liquid refrigerant moves.

### Advantageous Effects of Invention

According to the present invention, it is possible to provide a cooling device to exert sufficient cooling performance even in e.g. a thin electronic device, and an electronic device having the cooling device. Other objects, constituent elements and advantages besides those discussed above shall be apparent from the description of preferred embodiments of the invention which follows.

### BRIEF DESCRIPTION OF DRAWINGS

FIG. 1 A diagram showing the entire structure of a cooling device.

FIG. 2 A cross-sectional diagram showing the structure of a heat reception unit.

FIG. 3 A cross-sectional diagram showing the structure of a part between a boiling heat transfer unit and a base.

FIG. 4 A perspective diagram showing the structure of the boiling heat transfer unit.

FIG. 5 A diagram showing the structure of a condensation unit.

FIG. 6 A diagram showing the structure of a cover of the condensation unit.

FIG. 7 A diagram showing the structure of a part of the cover of the condensation unit.

FIG. 8 A diagram showing the structure of the condensation unit having asymmetric inclines.

FIG. 9 A diagram showing the structure of the condensation unit having a radiation fin unit on the base of the chamber.

### DESCRIPTION OF EMBODIMENTS

Hereinbelow, embodiments of the present invention will be described with reference to the drawings.

FIG. 1 is a diagram showing the entire structure of a cooling device 100. The cooling device 100 has a heat reception unit 101, a vapor tube 102, a condensation unit 103, a liquid tube 104, and refrigerant 107. The heat reception unit 101 is connected with the vapor tube 102 in a first connection 112. The heat reception unit 101 is connected with the liquid tube 104 in a second connection 113. Further, a chamber 105 of the condensation unit 103 is connected with the vapor tube 102 in a third connection 114. The chamber 105 is connected with the liquid tube 104 in a fourth connection 115.

A heat generating element 109 such as a semiconductor device (e.g. a processor) is mounted on a circuit board 110. The heat reception unit 101 having the refrigerant 107 inside is attached to the surface of the heat generating element 109. The heat generating element 109 and the heat reception unit 101 are thermally in contact with each other using TIM (Thermal Interface Material) such as thermal conductive grease. It is desirable that the first connection 112 and the second connection 113 are above the heat generating element 109 in a vertical direction.

The condensation unit 103 has the chamber 105 having a slope shape (or taper shape), and a radiation fin unit 106 connected with the chamber 105. A cooling fan 108 is installed in a position to generate a wind (cooling wind) and send the wind to the condensation unit 103 (especially the radiation fin unit 106). The direction of the wind is e.g. a direction indicated with numeral 111 in FIG. 1.

In the cooling device 100, the heat generated with the heat generating element 109 is transferred to the heat reception unit 101, and the liquid refrigerant 107 is vaporized (especially boiled) with the transferred heat to vapor (first phase change). The generated vapor refrigerant 107 moves from the heat reception unit 101 to the vapor tube 102, and further, moves through the vapor tube 102 to the chamber 105. The direction of movement of the vapor refrigerant 107 in the vapor tube 102 is e.g. a direction indicated with numeral 117 in FIG. 1.

The vapor refrigerant 107 in the chamber 105 is cooled with radiation with the radiation fin unit 106 or the chamber 105 which have received the wind sent from the cooling fan 108 and condensed (second phase change). Note that the heat of the vapor refrigerant 107 in the chamber 105 moves to the radiation fin unit 106 or the chamber 105. The moved heat is radiated to the outside air of the radiation fin unit 106 or the chamber 105.

The condensed liquid refrigerant 107 moves along the incline of the slope shape (or taper shape) of the chamber 105 with the gravity to the liquid tube 104, and returns through the liquid tube 104 to the heat reception unit 101. The direction of movement of the liquid refrigerant 107 in the liquid tube 104 is e.g. a direction indicated with numeral 118 in FIG. 1.

As described above, the cooling device 100 has a thermo-siphon based on a boiling cooling system which is capable of circulating the refrigerant 107 without external power such as a pump, but with the phase change (first and second phase changes) of the refrigerant 107 and the gravity.

It is desirable that the position of the first connection 112 in which the heat reception unit 101 and the vapor tube 102 are connected with each other is above an interface (gas interface) 116 of the refrigerant 107 in the vertical direction in the heat reception unit 101. Further, it is desirable that the position of the third connection 114 in which the chamber 105 and the vapor tube 102 are connected with each other is above the interface 116 of the refrigerant 107 in the vertical direction in the heat reception unit 101. It is desirable that the position of the fourth connection 115 in which the chamber 105 and the liquid tube 104 are connected with each other is above the interface 116 of the refrigerant 107 in the vertical direction in the heat reception unit 101.

On the other hand, it is desirable that the position of the second connection 113 in which the heat reception unit 101 and the liquid tube 104 are connected with each other is below or equivalent to the interface 116 of the refrigerant 107 in the vertical direction in the heat reception unit 101. Further, it is desirable that the position of the fourth connection 115 is above the second connection 113 in the vertical direction.

As described above, the cooling device 100 cools the heat generating element 109 by the phase change of the refrigerant 107. Accordingly, it is possible to attain high cooling efficiency by adopting e.g. water having high latent heat as the refrigerant 107. When cooling is performed using the refrigerant 107 with a high boiling point such as water at normal temperature, it is possible to increase the cooling efficiency by reducing the pressure inside the piping forming the circulation route through which the refrigerant 107 circulates (the heat reception unit 101, the vapor tube 102, the chamber 105, and the liquid tube 104) to lower the boiling point to promote phase change.

Further, it is desirable that the heat reception unit 101, the vapor tube 102, the chamber 105, and the liquid tube 104 are respectively formed with metal material (e.g. copper) having no corrosiveness (corrosion resistance) with respect to the refrigerant 107 (e.g. water). To maintain the inner pressure-reduced status, it is desirable that the respective junctions (the first connection 112, the second connection 113, the third connection 114, and the fourth connection 115) of the heat reception unit 101, the vapor tube 102, the chamber 105, and the liquid tube 104 are brazed or welded. It is desirable that the radiation fin unit 106 is formed with material with a high thermal conductivity such as copper or aluminum.

Further, when organic refrigerant having a low boiling point such as hydrofluoroether as the refrigerant 107, it is possible to attain high cooling efficiency without pressure reduction inside the piping (the heat reception unit 101, the vapor tube 102, the chamber 105, and the liquid tube 104) forming the circulation route for the refrigerant 107. Further, when there is no need for pressure reduction as in this case, it is possible to use a deformable material such as a silicone tube or a rubber tube, as the vapor tube 102 and the liquid tube 104. It is possible, by using the deformable material such as the vapor tube 102 and the liquid tube 104, to freely change the position of the condensation unit 103 even when the heat reception unit 101 is fixed, to increase the freedom of position and range of attachment of the cooling device 100.

The material of the refrigerant 107 is not particularly limited as long as it is refrigerant which is boiled with the heat transferred from the heat generating element 109. Further, the material used as the heat reception unit 101 and the chamber 105 is also not particularly limited as long as it has no corrosiveness (corrosion resistant) with respect to the refrigerant 107 and it has high thermal conductivity.

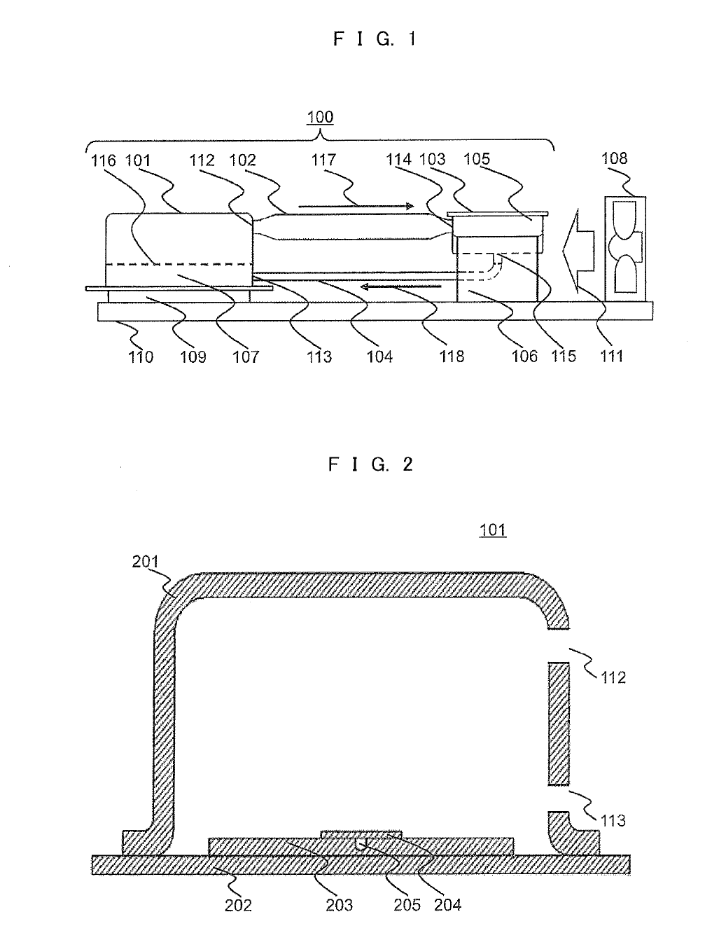

FIG. 2 is a diagram showing the structure of the heat reception unit 101. It is desirable that the heat reception unit 101 has a structure to promote boiling of the liquid refrigerant 107 in the heat reception unit 101 (boiling promoting structure). The structure will be described using FIGS. 2 to 4.

The heat reception unit 101 has a cover 201, a base 202 which is thermally in contact with the heat generating element 109, and a boiling heat transfer unit 203 located inside the cover 201 and on the base 202. For example, on the base 202 which is a rectangular-shaped metal member with excellent thermal conductivity formed of copper or aluminum, the cover 201 also formed by shaping metal material into a bowl shape is placed, and is brazed or welded.

As the first connection 112 and the second connection 113, through holes are formed in two upper and lower positions in a side surface of the cover 201. The vapor tube 102 is connected with the upper through hole, and the liquid tube 104 is connected with the lower through hole. That is, the position of the first connection 112 is above the position of the second connection 113 in the vertical direction.

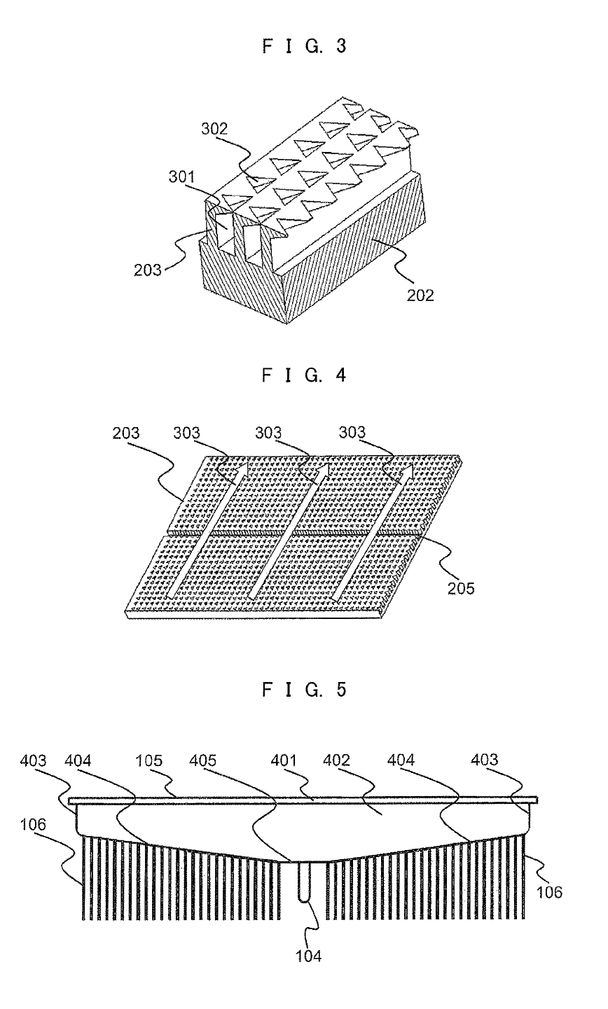

FIG. 3 is a cross-sectional diagram showing the structure of a part between the boiling heat transfer unit 203 and the base 202. FIG. 4 is a perspective diagram showing the structure of the boiling heat transfer unit 203. FIG. 3 and FIG. 4 lack a roof plate 204. The boiling heat transfer unit 203 may be formed by processing the base 202.

As shown in FIG. 2 to FIG. 4, the boiling heat transfer unit 203 has plural tunnel structures (tunnels) 301 having plural holes 302 in upper parts, a groove 205 deeper than the plural tunnel structures 301, and the roof plate (plate) 204 on the groove 205. It is desirable that the roof plate 204 is of the same metal as that of the base 202. It is desirable that the groove 205 is located at the center of the boiling heat transfer unit 203. It is desirable that the direction of the groove 205 is different from a tunnel direction 303 and it is more desirable the direction of the groove is orthogonal to the tunnel direction 303.

The plural tunnel structures 301 are arranged in parallel. In the tunnel structures 301, the plural holes 302 are provided at fixed intervals in the tunnel direction 303. The tunnel structures 301 communicate with the space in the heat reception unit 101 via the holes 302.

With this structure of the boiling heat transfer unit 203, the bottom surface of the Groove 205 close to the heat generating element 109 is locally at a high temperature, to promote generation of bubbles as the start of boiling. The generated bubbles spread over the entire boiling surface through the tunnel structures 301 and the space formed with the groove 205 and the roof plate 204. The spread bubbles maintain the continuous boiling through the holes 302 communicating with the tunnel structures 301. With the above structure of the boiling heat transfer unit 203, stable start of boiling and improvement in boiling heat transfer performance are realized.

FIG. 5 is a diagram showing the structure of the condensation unit 103. FIG. 5 is a diagram of the condensation unit 103 and the liquid tube 104 viewed from the direction indicated with numeral 111 in FIG. 1. The condensation unit 103 has the chamber 105 formed in a slope shape (or taper shape) and the radiation fin unit 106 connected with the chamber 105.

The chamber 105 has a rectangular-shaped base 401 formed of metal material with excellent thermal conductivity such as copper or aluminum, and a cover 402, brazed or welded to the base 401, formed by shaping into a slope shape (or taper shape). The cover 402 has a side 403 connected with the base 401, an inclined section 404 having inclines, and a bottom 405 connected with the liquid tube 104.

The liquid refrigerant 107 condensed with the condensation unit 103 moves, with the incline of the inclined section 404, from the inclined section 404 to the bottom 405, and further, moves to the liquid tube 104. It is possible to efficiently move the liquid refrigerant 107 to the liquid tube 104 by connecting the bottom 405 to the liquid tube 104 in low positions in the vertical direction in the chamber 105.

The radiation fin unit 106 is connected with the chamber 105 by brazing or welding. It has plural fins of metal with excellent thermal conductivity. It is desirable that the respective fins of the radiation fin unit 106 have a length variable in accordance with inclination angle of the inclined section 404. It is desirable that the respective fins are set with the respective fin directions along the vertical direction.

The position at which a fin positioned close to the liquid tube 104 (or the bottom 405) is connected with the inclined section 404 is below the position at which a fin in a farther position is connected with the inclined section 404 (or in a position close to the circuit board 110) in the vertical direction. It is desirable that the fin close to the liquid tube 104 (or the bottom 405) has a length shorter than that of the fin in the farther position in the vertical direction. With this configuration, e.g. when the height positions in the vertical direction in which the fins are connected with the circuit board 101 (or an installation part for installation on the circuit board 101) are aligned with each other, the installation of the radiation fin unit 106 on the circuit board 101 (or an installation part for installation on the circuit board 101) is facilitated. The fins may be connected with the bottom 405.

In another embodiment, it may be configured such that the respective fins of the radiation fin unit 106 have a slope shape along the incline of the inclined section 404 and are connected with the inclined section 404. In the other embodiment, regarding the connection positions between the respective fins and the inclined section 404, the connection position of a fin closer to the liquid tube 104 (or the bottom 405) is lower. In this embodiment, in the respective fins, to facilitate installation on the circuit board 101 (or an installation part for installation on the circuit board 101), it is desirable that the length of a fine closer to the liquid tube 104 (or the bottom 405) is shorter in the vertical direction.

In the cover 402, through holes are formed in the side 403 and the bottom 405 as the third connection 114 and the fourth connection 115. The vapor tube 102 is connected with the upper through hole, and the liquid tube 104 is connected with the lower through hole. That is, the position of the third connection 114 is above the position of the fourth connection 115 in the vertical direction.

The vapor refrigerant 107 moves through the vapor tube 102 into the chamber 105 and is condensed. The condensed liquid refrigerant 107 moves smoothly by the gravity along the incline of the inclined section 404. Further, the refrigerant moves through the bottom 405 to the liquid tube 104 (is transported). With this structure, since the condensed liquid refrigerant 107 does not stay in the condensation heat transfer surface (e.g. the inclined section 404), it is possible to improve the condensation performance.

The inclined section 404 has two or more inclines in different directions. For example, it has two inclines symmetrically or asymmetrically on the both sides of the liquid tube 104 (or the bottom 405). For example, when the chamber 105 has a conic shape or pyramid shape, the inclined section 404 has a large number of inclines in different directions.

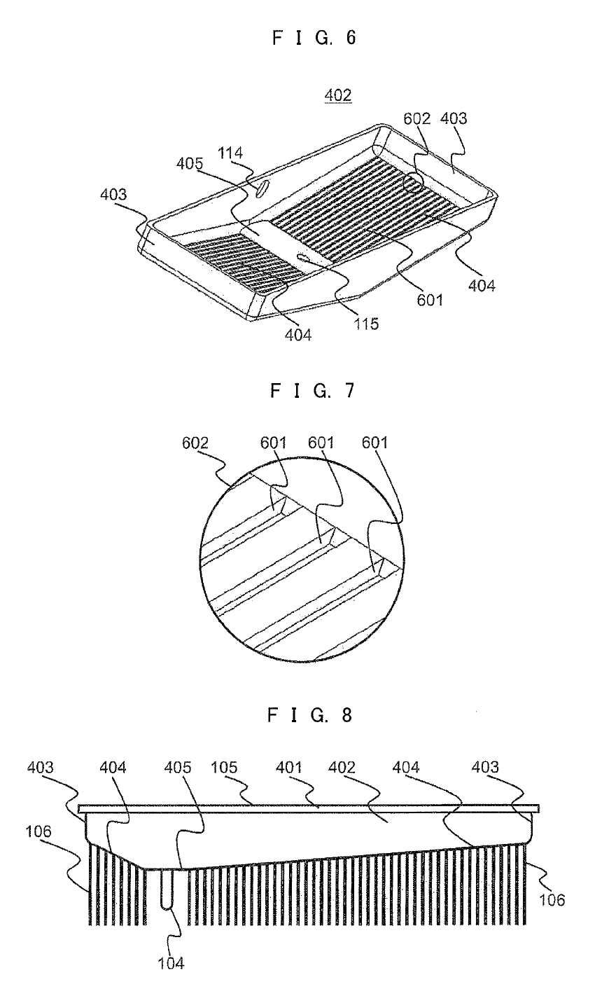

FIG. 6 is a diagram showing the structure of the cover 402 of the condensation unit 103. FIG. 7 is a diagram showing the structure of a part 602 in FIG. 6.

The inclined section 404 has plural fine grooves 601 (e.g. having a depth of 0.1 mm, a width of 0.1 mm, and a pitch of 0.3 mm) along a direction where the condensed liquid refrigerant 107 flows, i.e., inclination direction of the inclined section 404. With the chamber 105 provided with the fine grooves 601 in its inner wall, the movement (transport) of the condensed liquid refrigerant 107 is promoted with the capillary force of the fine grooves 601. Further, since the wet condition is always maintained inside the grooves 601, it is possible to suppress the growth of droplet of the condensed refrigerant 107 and to improve the condensation thermal conductivity.

According to the structure of the condensation unit 103 according to the present embodiment, one chamber structure has three functions: a function of receiving the vapor refrigerant 107 from the vapor tube 102; a function of condensing (radiating) the vapor refrigerant 107; and a function of collecting the condensed liquid refrigerant 107 and send it to the liquid tube 104.

Since the cooling device 100 according to the present embodiment realizes three functions with one condensation unit 103 as described above, the space is saved. Further, the saved space may be used for enlargement of the radiation fin unit 106. Accordingly, in comparison with the conventional cooling device in e.g. Patent Literature 1, it is possible to greatly improve the cooling performance. Note that in the conventional cooling device in e.g. Patent Literature 1 these three functions are realized by respectively using the three structures, the upper header, the flat tube (cooling tube), and the lower header.

For example, in a rack server in the minimum unit size of 1 U (1.75 inch=44.45 mm) determined with the Electronics Industries Alliance (EIA), considering the heights of the circuit board and the CPU socket, the space allowed for the cooling device is about 30 mm. In the cooling device 100 according to the present embodiment, in e.g. the condensation unit 103, about 10 mm space is used for the chamber 105 installed in the upper part, and all the remaining space of about 20 mm, for installation space of the radiation fin unit 106, as shown in FIG. 1.

Further, in the cooling device 100 according to the present embodiment, it is possible to fully utilize the space allowed by changing the lengths of the respective fins of the radiation fin unit 106 in accordance with the incline (taper) of the inclined section 404 and aligning the directions in the vertical direction. As a result, it is possible to incorporate the cooling device 100 in a thin type electronic device such as a server in thickness size of 1 U (44.45 mm) or a thin blade server.

FIG. 8 is a diagram showing another embodiment in the structure of the condensation unit 103. Regarding the incline of the inclined section 404 of the chamber 105, a lower end of the incline (or the bottom 405) is shifted from the center of the chamber 105. In the condensation unit 103, the inclined section 404 has two or more inclines at different angles. The inclined section 404 has asymmetric inclines on the both sides of the bottom 405 (or the liquid tube 104).

As shown in FIG. 8, it is possible to control the connection position of the vapor tube 102 or the liquid tube 104 by changing e.g. the position or angle of the incline (taper) of the inclined section 404. Accordingly, it is possible to freely design the installation position or size of the condensation unit 103 in accordance with electronic equipment in which the unit is installed.

Note that when a rectangular parallelepiped chamber, in an inclined status, is installed, and the vapor tube is connected with the upper part and the liquid tube is connected with the lower part, the position where the rectangular parallelepiped chamber is connected with the vapor tube (or the liquid tube) is limited. Accordingly, in comparison with the structure of the condensation unit 103 according to the present embodiment, the freedom of design is low.

Further, in the rectangular parallelepiped chamber structure, since the bottom surface of the chamber is inclined in only one direction, when the height of the cooling device is lowered in accordance with reduction of height and thickness of the electronic device, the inclination is limited to small. Accordingly, refrigerant does not efficiently flow, and the condensation performance is lowered. On the other hand, in the structure of the condensation unit 103 according to the present embodiment, since there are two or more inclines in different directions, it is possible to increase the inclination of the inclined section 404 and to efficiently flow the refrigerant 107 to the liquid tube 104. Accordingly, it is possible to maintain or improve the condensation performance even when the height and thickness of the electronic device are reduced.

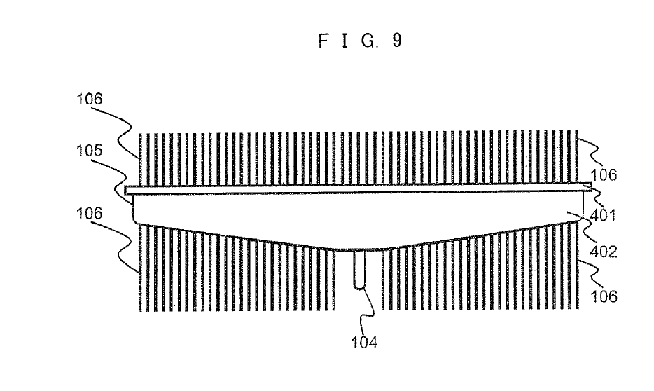

FIG. 9 is a diagram showing the structure of the condensation unit 103 having the radiation fin unit 106 on the base 401. In the condensation unit 103, the radiation fin unit 106 having plural fins is provided on the base 401 on the chamber 105. That is, in the condensation unit 103, the radiation fin unit 106 is installed in the inclined section 404, the bottom 405 or the base 401 in the chamber 105. It is possible to freely design the shape of the radiation fin unit 106 in accordance with electronic device in which it is installed.

In the cooling device 100 according to the present embodiment, the circulation route for the refrigerant 107 is formed with the heat reception unit 101, the vapor tube 102, the condensation unit 103, and the liquid tube 104. The refrigerant 107 is circulated by phase change of the refrigerant 107 inside the cooling device 100. The condensation unit 103 has the chamber 105 connected with the vapor tube 102 and the liquid tube 103 and the radiation fin unit 106 connected with the chamber 105. The bottom surface of the chamber 105 is formed in a slope shape (or taper shape).

In the cooling device 100 according to the present embodiment, even when it is installed in an e.g. thin electronic device and the height (vertical direction) is low, since the inclined section 404 has two or more inclines (or tapers) in different directions, sufficient space in which the condensation unit 103 (especially the inclined section 404 and the radiation fin unit 106) is installed is ensured in accordance with the position, angle and size of the inclines. It is possible to exert sufficient cooling performance.

### REFERENCE SIGNS LIST

100: cooling device, 101: heat reception unit, 102: vapor tube, 103: condensation unit, 104: liquid tube, 105: chamber, 106: radiation fin unit, 107: refrigerant, 108: cooling fan, 109: heat generating element, 110: circuit board, 401: base, 402: cover, 403: side, 404: inclined section, and 405: bottom.

1. A cooling device comprising:
a heat reception unit that vaporizes refrigerant;
a vapor tube connected with the heat reception unit, through which the vaporized refrigerant moves;
a condensation unit, having an inclined section having inclines in at least two directions and two or more members connected with the inclines of the inclined section, that condenses the vaporized refrigerant that has moved through the vapor tube; and
a liquid tube connecting the condensation unit to the heat reception unit, through which the condensed liquid refrigerant moves.

2. The cooling device according to claim 1,
wherein the two or more members include a first member and a second member in a position farther from the liquid tube than the first member, and
wherein a position at which the first member and the inclined section are connected with each other is below a position at which the second member and the inclined section are connected with each other in a vertical direction.

3. The cooling device according to claim 1,
wherein the liquid tube is connected with a bottom of the condensation unit,
wherein the two or more members include a third member and a fourth member in a position farther from the bottom than the third member, and
wherein a position at which the third member and the inclined section are connected with each other is below a position at which the fourth member and the inclined section are connected with each other in a vertical direction.

4. The cooling device according to claim 2,
wherein the liquid tube is connected with a bottom of the condensation unit,
wherein a position at which the liquid tube and the bottom are connected with each other is vertically above a position at which the heat reception unit and the liquid tube are connected with each other, and
wherein the liquid refrigerant, condensed with the condensation unit, moves from the inclined section to the bottom, and further moves to the liquid tube.

5. The cooling device according to claim 4, wherein the position at which the condensation unit and the vapor tube are connected with each other is above the position at which the bottom of the condensation unit and the liquid tube are connected with each other in the vertical direction.

6. The cooling device according to claim 5, wherein the inclined section has a plurality of grooves along directions of the inclines.

7. The cooling device according to claim 6, wherein the inclined section has two or more inclines at different inclination angles.

8. The cooling device according to claim 7, wherein in the first member, a length in a vertical direction is shorter than the second member.

9. The cooling device according to claim 8, having a third member on the condensation unit.

10. The cooling device according to claim 9, wherein the heat reception unit has a boiling heat transfer unit having: a tunnel structure with a plurality of holes in an upper part, a groove deeper than the plurality of tunnel structures, and a plate on the groove.

11. The cooling device according to claim 1, wherein the two or more members have shapes along the inclines of the inclined section.

12. An electronic device in which the cooling device according to claim 1 is mounted.

13. The electronic device according to claim 12, having a fan that sends a wind to the condensation unit.
